(19) United States
(12) Patent Application Publication
(10) Pub. No.: US 2011/0204433 A1
(43) Pub. Date: Aug. 25, 2011

(54) NONVOLATILE SEMICONDUCTOR STORAGE DEVICE AND METHOD OF MANUFACTURING THE SAME

(75) Inventors: Junya FUJITA, Yokkaichi (JP); Masayuki TANAKA, Yokohama (JP); Shunsuke DOI, Yokkaichi (JP)

(73) Assignee: KABUSHIKI KAISHA TOSHIBA, Tokyo (JP)

(21) Appl. No.: 12/956,591

(22) Filed: Nov. 30, 2010

(30) Foreign Application Priority Data
Feb. 25, 2010 (JP) 2010-040212

(51) Int. Cl. H01L 29/792; H01L 21/28

(52) U.S. Cl. 257/326; 438/591; 257/E29.309; 257/E21.21

(57) ABSTRACT

A nonvolatile semiconductor storage device is disclosed. The nonvolatile semiconductor storage device includes a semiconductor substrate including a surface layer; an element isolation insulating film isolating the surface layer of the semiconductor device into a plurality of active regions; a first gate insulating film formed above the active regions; a charge storing layer formed above the first gate insulating film and including a silicon layer containing an upper layer selectively doped with carbon; a second gate insulating film formed above the charge storing layer; and a control gate electrode formed above the second gate insulating film.

### CROSS-REFERENCE TO RELATED APPLICATION(S)

This application is based upon and claims the benefit of priority from Japanese Patent Application No. 2010-40212, filed on, Feb. 25, 2010 the entire contents of which are incorporated herein by reference.

### FIELD

Exemplary embodiments disclosed herein generally relate to a nonvolatile semiconductor storage device provided with a charge storing layer and a method of manufacturing such nonvolatile semiconductor storage device.

### BACKGROUND

Typical nonvolatile semiconductor storage device such as NAND flash memory is primarily configured by memory cell transistors. A memory cell transistor is often implemented in a laminate structure where gate insulating film, charge storing layer typically configured as a floating gate electrode, inter-electrode insulating film, and control gate electrode are formed above a semiconductor substrate in the listed sequence. Such laminate structure is likely to result in higher aspect ratio topography with advances in microfabrication. One of the problems encountered in high aspect ratio topography is structure collapse.

In features including laminate structures such as NAND flash memory, there is greater technical challenges in reducing elevation as compared to reducing planar dimension. Thus, in a lithography process, for instance, attempts to reduce the thickness of masks used for pattern formation have failed, and to date, patterns are formed under increasingly higher aspect ratios as the patterns become denser. Higher aspect ratio results in greater possibility of structure collapse or pattern collapse which is one of the major factors that lead to yield degradation. A possible solution to prevent yield degradation originating from the lithography process may be changing the ingredients of the mask to those that provide lower aspect ratios.

Conventionally, when employing an STI (Shallow Trench Isolation) scheme, an element isolation trench is typically overfilled with an oxide film which is thereafter planarized by CMP (Chemical Mechanical Polishing). During the CMP, a silicon nitride film or laminate layers of films were used as a polish stop. The provision of the polish stop was one of the factors that lead to the increase in aspect ratio. However CMP performed in the absence of the polish stop disadvantageously suffered scratches on the surface of polycrystalline silicon film.

### BRIEF DESCRIPTION OF THE DRAWINGS

FIG. 1 is a partial equivalent circuit representation of a memory cell array according to one exemplary embodiment of the present disclosure;

FIG. 2 is a schematic plan view partially illustrating an array of transistors within a memory cell region;

FIG. 3A is a schematic vertical cross-sectional view taken along line 3A-3A in FIG. 2;

FIG. 3B is a schematic vertical cross-sectional view taken along line 3B-3B in FIG. 2;

FIGS. 4A, 5A, 6A, 7A, 8A, 9A, 10A, 11A, 12A, 13A, 14A, 15A, 16A, 17A, 18A, 19A, and 20A each schematically describes a vertical cross-sectional view of 1 out of 17 manufacturing phases of the portion taken along line 3A-3A of FIG. 2;

FIGS. 4B, 5B, 6B, 7B, 8B, 9B, 10B, 11B, 12B, 13B, 14B, 15B, 16B, 17B, 18B, 19B, and 20B, each schematically describes a vertical cross-sectional view of 1 out of 17 manufacturing phases of the portion taken along line 3B-3B of FIG. 2;

FIG. 21A is a schematic plan view illustrating a resistor within a peripheral circuit region; and

FIG. 21B is a schematic vertical cross sectional view taken along line 21B-21B of FIG. 21A.

### DETAILED DESCRIPTION

In one exemplary embodiment, a nonvolatile semiconductor storage device is disclosed. The nonvolatile semiconductor storage device includes a semiconductor substrate including a surface layer; an element isolation insulating film isolating the surface layer of the semiconductor device into a plurality of active regions; a first gate insulating film formed above the active regions; a charge storing layer formed above the first gate insulating film and including a silicon layer containing an upper layer selectively doped with carbon; a second gate insulating film formed above the charge storing layer; and a control gate electrode formed above the second gate insulating film.

In one exemplary embodiment, a method of manufacturing a nonvolatile semiconductor storage device is disclosed. The method includes preparing a semiconductor substrate; forming a first gate insulating film above the semiconductor substrate; forming a charge storing layer above the first gate insulating film, the charge storing layer including a silicon layer being doped with carbon at least in an upper layer thereof; forming an element isolation trench into the semiconductor substrate through the charge storing layer and the first gate insulating film; filling the element isolation trench with an insulating film; polishing the insulating film until an upper surface of the charge storing layer is exposed and the insulating film remains in the element isolation trench to obtain an element isolation insulating film; forming a second gate insulating film above the charge storing layer after forming the element isolation insulating film; and forming a control gate electrode above the second gate insulating film.

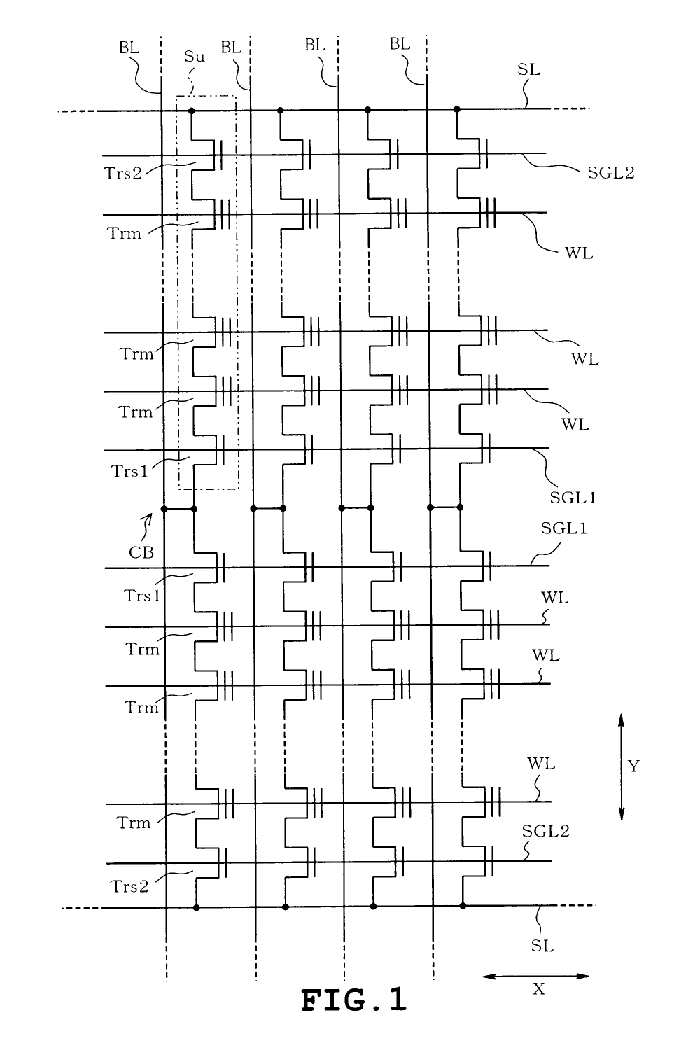

One exemplary embodiment is described hereinafter through a NAND flash memory application. References are made from time to time to the accompanying drawings labeled as FIGS. 1 to 21B to provide an illustration of the features of the exemplary embodiment. Elements that are identical or similar are represented by identical or similar reference symbols across the figures. The drawings are not drawn to scale and thus, do not reflect the actual measurements of the features such as the correlation of thickness to planar dimensions and the relative thickness of different layers.

First, a description will be given on the basic configuration of a NAND flash memory according to one exemplary embodiment.

FIG. 1 is a partial equivalent circuit representation of a memory cell array formed in the memory cell region of the NAND flash memory. The memory cell array is a collection of units of NAND cells also referred to as NAND cell unit Su or memory unit Su arranged in rows and columns. NAND cell unit Su comprises a multiplicity of series connected memory cell transistors Trm, such as 16 or 32 in number, situated between a couple of select gate transistors Trs1 and Trs2. The neighboring memory cell transistors Trm within NAND cell unit Su share their source/drain regions.

Still referring to FIG. 1, the X-direction aligned memory cell transistors Trm are interconnected by common word line WL or control gate line WL, whereas the X-direction aligned select gate transistors Trs1 are interconnected by common select gate line SGL1 and likewise, the X-direction aligned select gate transistors Trs2 are interconnected by common select gate line SGL2. The drain of each select gate transistor Trs1 is coupled to bit line BL by way of bit line contact CB. Bit line BL extend in the Y direction orthogonal to the X direction. The source of select gate transistor Trs2 is coupled to source line SL extending in the X-direction.

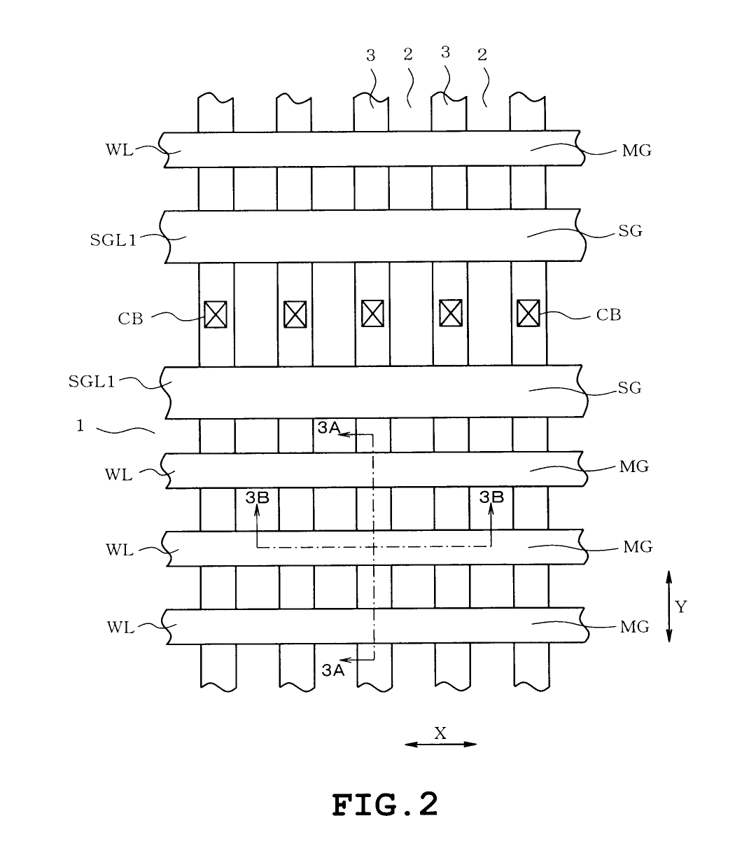

FIG. 2 provides a planar layout of memory cell region in part. As shown, multiplicity of element isolation insulating films 2 run in the Y direction of p conductive type silicon substrate 1, or more generally, the semiconductor substrate, to isolate active regions 3 by a predetermined space interval in the X direction. The isolation typically employs a shallow trench isolation scheme. Multiplicity of X-directional word lines WL run above element isolation film 2 and active region 3 so as to be orthogonal to active regions 3 extending in the Y direction. Word line WL is connected to the control gate electrode provided at each of the memory cell transistors.

Still referring to FIG. 2, in active region 3 located between a couple of X-directional select gate lines SGL1 that are each connected to select gate transistors, bit line contact CB is formed. Bit line contact CB is coupled to an overlying bit line BL running in the Y direction though not shown in detail in FIG. 2. Gate electrode MG of a memory cell transistor is formed in active region 3 where word line WL crosses over, whereas gate electrode SG of a select gate transistor is formed in active region 3 where select gate line SGL1/SGL2 crosses over.

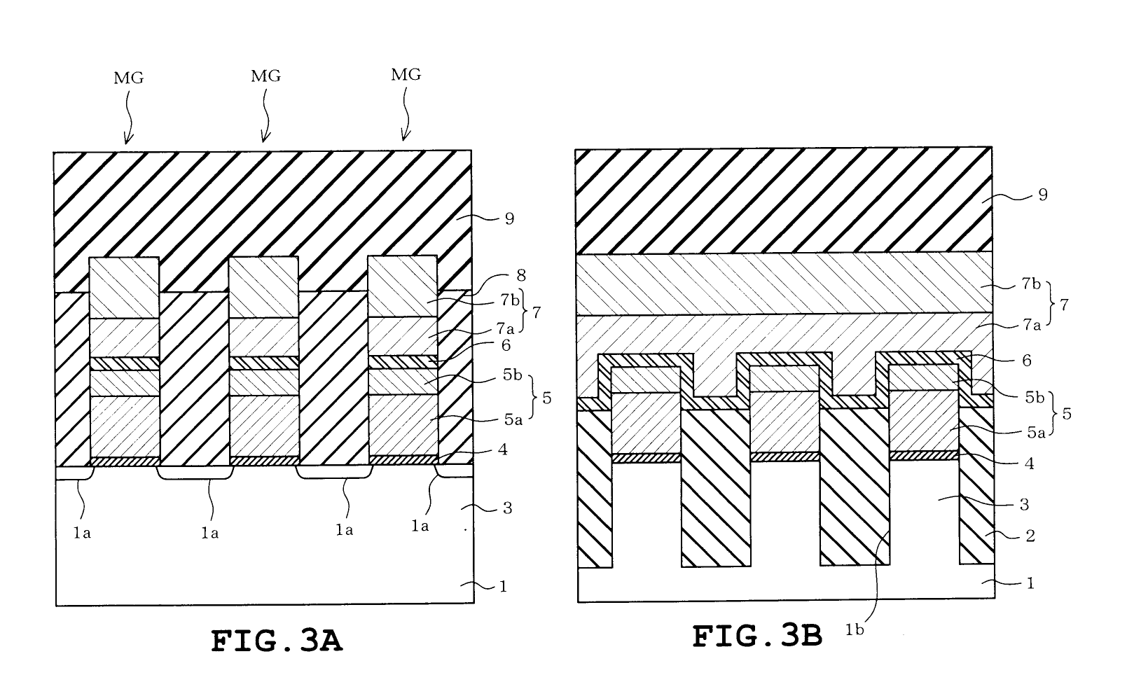

FIGS. 3A and 3B are schematic vertical cross sectional views taken along lines 3A-3A and 3B-3B of FIG. 2. More specifically, FIG. 3A is a cross section of the memory cell transistor taken along active region 3 or the Y direction to show the cross section of the gate electrode MG, whereas FIG. 3B is a cross section taken along word line WL or the X direction to provide an alternative view.

FIG. 3A shows gate electrodes MG formed at a predetermined space interval above gate insulating film 4, also referred to as a first gate insulating film, which is formed in active region 3 of semiconductor substrate 1. Gate electrode MG is formed by laminating at least floating gate electrode 5 serving as a charge storing layer, inter-electrode insulating film 6, and control gate electrode 7 in the listed sequence above gate insulating film 4.

Gate insulating film 4 is made of silicon oxynitride (SiON) which is, for instance, 8 nm thick. Floating gate electrode 5 is configured by laminating lower polycrystalline silicon film 5a and upper polycrystalline silicon film 5b in the listed sequence. Lower polycrystalline silicon film 5a is doped with phosphorous (P) or arsenic (As) in a dopant concentration ranging between 1×10²⁰ to 1×10²¹ atoms/cm³ and is approximately 60 nm thick. Upper polycrystalline silicon film 5b is also doped with phosphorous (P) or arsenic (As) in a dopant concentration ranging between 1×10²⁰ to 1×10²¹ atoms/cm³. Upper polycrystalline silicon film 5b is further doped with carbon (C) in a dopant concentration of 1×10¹⁸ atoms/cm³ or greater, typically ranging between 2×10²⁰ to 2×10²¹ atoms/cm³ , and is approximately 30 nm thick.

Lower polycrystalline silicon film 5a and upper polycrystalline silicon film 5b constituting floating gate electrode 5 in the memory cell region serves as a gate electrode and a passive element such as a resistor in the peripheral circuit region. When used as a resistor, resistance can be controlled through adjustment in the dopant concentration of carbon within the upper and lower polycrystalline silicon films 5b and 5a. For instance, increasing the dopant concentration of carbon (C) within an ordinary polycrystalline silicon film increases the resistance of the polycrystalline silicon film.

On top of floating gate electrode 5, inter-electrode insulating film 6 is formed which is also referred to as a second gate insulating film. Inter-electrode insulating film 6 is configured, for instance, by an ONO (Oxide—Nitride—Oxide) film and each of the three film layers is controlled to a thickness ranging between 2 nm to 10 nm. Inter-electrode insulating film 6 may alternatively be configured by a NONON (Nitride—Oxide—Nitride—Oxide—Nitride) film or by an insulating film having a high dielectric constant.

On top of inter-electrode film 6, control gate electrode 7 is formed which is configured by laminating polycrystalline silicon layer 7a doped with impurities and silicide layer 7b comprising, for instance, a nickel silicide (NiSi) film in the listed sequence. Control gate electrode 7 may be fully silicided so as to soley comprise silicide layer 7b. Gate electrode MG of the memory cell transistor in the memory cell region is configured as described above.

In the surface layer of silicon substrate 1, n-type impurity diffusion layer la serving as the source/drain region is formed between the neighboring gate electrodes MG. The neighboring memory cell transistors are connected electrically and serially through impurity diffusion region 1a.

Between gate electrodes MG, inter-cell insulating film 8 is formed so as to fill the gaps between gate electrodes MG. Interlayer insulting film 9 is further blanketed over inter-cell insulating film 8. Inter-cell insulating film 8 is made, for instance, of a TEOS (Tetraethylorthosilicate) oxide film. The upper surface of inter-cell insulating film 8 is substantially at level with the mid elevation of silicide layer 7b of control gate electrode 7. Such adjustment in the elevation of inter-cell insulating film 8 is made in anticipation of silicidation of the upper portion of polycrystalline silicon film 7c to obtain silicide layer 7b as later described in the manufacturing process flow.

Referring now to FIG. 3B, the surface layer of silicon substrate 1 has element isolation trenches 1b formed into it. Each element isolation insulation trench 1b is filled with the aforementioned element isolation insulating film 2 which comprises, for instance, a silicon oxide film formed by techniques such as CVD (Chemical Vapor Deposition) and coating. Above each active region 3, gate insulating film 4, lower and upper polycrystalline silicon films 5a and 5b are laminated in the listed sequence.

The upper portion of element isolation insulating film 2 is etched down after its formation so that its upper surface is located at an elevation between the upper and lower surfaces of lower polycrystalline silicon film 5a. Inter-electrode insulating film 6 is formed so as to cover the upper surface and sidewalls of upper polycrystalline silicon film 5b, upper sidewall of lower polycrystalline silicon film 5a, and the upper surface of element isolation insulating film 2. Polycrystalline silicon layer 7a of control gate electrode 7 is blanketed above the entire underlying structure to cover the upper surface of inter-electrode insulating film 6. Silicide layer 7b is formed above polycrystalline silicon layer 7a and interlayer insulating film 9 is further formed so as to cover the upper surface of silicide layer 7b and inter-cell insulating film 8.

According to the above described configuration, because upper polycrystalline silicon film 5b of floating gate electrode 5 is doped with carbon in the aforementioned dopant concentration, it can be reinforced in hardness as compared to carbon-free polycrystalline silicon to be advantageously utilized as a stopper film, in this case, a polish stop in CMP.

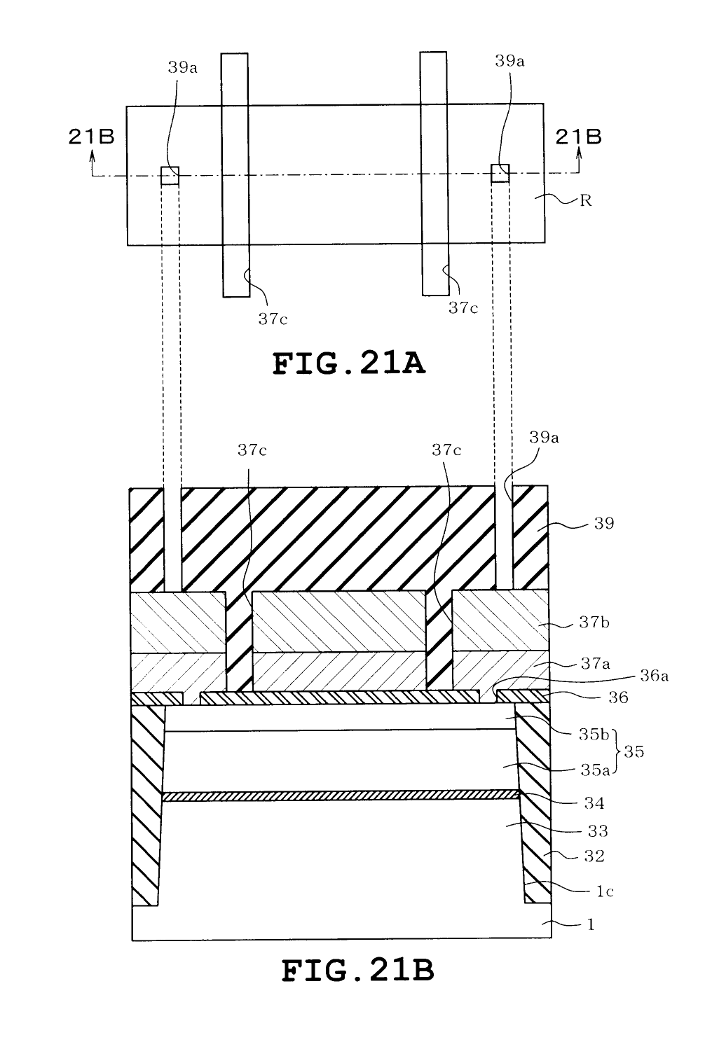

FIGS. 21A and 21B illustrate resistor R as one example of the gate electrode configuration in the memory cell region being applied to a passive element formed in the peripheral circuit region as indicated earlier. FIG. 21A shows a planar layout of a rectangular resistor R whereas FIG. 21B is schematic cross sectional view taken along line 21B-21B of FIG. 21A.

Resistor R is formed in active region 33 serving as an element forming region which is surrounded by trench 1c. Trench 1c is filled with element isolation insulating film 32 just like element isolation insulating film 2 applied in the memory cell region. As was the case in the memory cell transistors formed in the memory cell region, gate insulating film 34, lower polycrystalline silicon film 35a and upper polycrystalline silicon film 35b are laminated in the listed sequence so as to be in alignment with the sidewall of trench 1c. Element isolation insulating film 32 is formed so as to be substantially at level with upper polycrystalline silicon film 35b.

Above the upper surfaces of upper polycrystalline silicon film 35b and element isolation insulating film 32, inter-electrode insulating film 36 corresponding to inter-electrode insulating film 6 is formed which has rectangular openings 36a as can be seen FIG. 21B. Openings 36a are formed when forming similar openings for shorting the select gate transistors of the memory cell region and the transistors of the peripheral circuit region. Above inter-electrode insulating film 36, polycrystalline silicon layer 37a and silicide layer 37b are laminated in the listed sequence as was the case in control gate electrode 7 of the memory cell region. Polycrystalline silicon layer 37a contacts upper polycrystalline silicon film 35b through openings 36a formed on inter-electrode insulating film 36. As can be seen in FIGS. 21A and 21B, polycrystalline silicon layer 37a and silicide layer 37b are separated in the lengthwise direction or the longer side direction of resistor R at separations 37c, two of which are shown. Further, interlayer insulating film 39 is formed to overfill separations 37c and to consequently cover polycrystalline silicon layer 37a and silicide layer 37b. As shown in FIGS. 21A and 21B, contact holes 39a, two in this example, are formed so as to reside on separated locations along the lengthwise direction of resistor R to expose the upper surface of silicide layer 37b. Each contact hole 39a is filled with a contact plug.

According to resistor R configured as described above, the laminate of lower polycrystalline silicon film 35a and upper polycrystalline silicon film 36b above gate insulating film 34 serves as a resistor and the extremities of polycrystalline silicon layer 37a and silicide layer 37b, as viewed in FIG. 21B, separated by separations 37c serve as electrode terminals. An electrode is drawn out above each of the electrode terminals through the contact plug to establish connection with the overlying wiring layer.

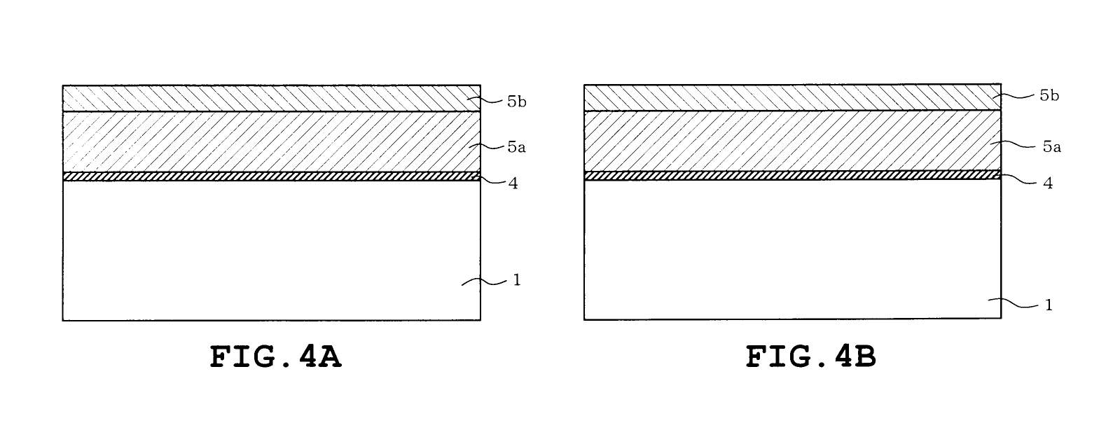

Next, a description will be given on the method of manufacturing the above described features with reference to FIGS. 4A to 20B. Symbols “A” and “B” appended to each of the figures indicate their association with FIGS. 3A and 3B, meaning that they show the cross sections taken at FIGS. 3A and 3B at different stages of the manufacturing process flow. The manufacturing process flow described hereinafter is primarily directed to or based on the formation of the memory cell transistor shown in FIGS. 3A and 3B, however, the aforementioned resistor R can be formed in substantially the same way.

Referring first to FIGS. 4A and 4B, gate insulating film 4 is formed above a surface layer of p conductive type silicon substrate 1. Gate insulating film 4 comprises a silicon oxynitride film which has a thickness ranging between 1 nm to 15 nm made by a combination of known thermal oxidation and thermal nitridation schemes. Gate insulating film 4 of the present exemplary embodiment is 8 nm thick. Then, above the gate insulating film 4, lower polycrystalline silicon film 5a doped with phosphorous (P) is formed which is further topped by upper polycrystalline silicon film 5b doped with phosphorous and carbon. Phosphorous, which is a dopant to both lower and upper polycrystalline silicon film 5a and 5b, may be replaced by arsenic (As).

Lower and upper polycrystalline silicon films 5a and 5b are formed by a well known LPCVD (Low Pressure Chemical Vapor

Deposition) using source gases such as monosilane (SiH₄), phosphine (PH₃), and ethylene (C₂H₄) gas in the temperature ranging between 500 to 600 degrees Celsius. The use of ethylene gas in the formation of upper polycrystalline silicon film 5b incorporates carbon into upper polycrystalline silicon film 5b. Lower polycrystalline silicon film 5a is formed to be 60 nm thick, for instance, whereas upper polycrystalline silicon film 5b is formed thinner so as to be 30 nm thick, for instance.

The dopant concentration of phosphorus (P) or arsenic (As) to lower polycrystalline silicon film 5a and upper polycrystalline silicon film 5b ranges between 1×10²⁰ to 1×10 10²¹ atoms/cm³. The dopant concentration of carbon to upper polycrystalline silicon film 5b is 1×10¹⁸ atoms/cm³ or greater and typically ranges between 2×10²⁰ to 2×10²¹ atoms/cm³. Further, lower polycrystalline silicon film 5a and upper polycrystalline silicon film 5b may be post-crystallized by thermal crystallization process if formed as amorphous.

The thicknesses of lower polycrystalline silicon film 5a and upper polycrystalline silicon film 5b may be determined depending upon the level of resistance they need to possess to meet the required electric properties of floating gate electrode 5 and other elements such as the aforementioned resistor R formed in the peripheral circuit region. The level of resistance increases with the amount of added carbon, and thus, resistance can be fine tuned through adjustment in the amount of carbon, which in turn determines the thicknesses of lower polycrystalline silicon film 5a and upper polycrystalline silicon film 5b.

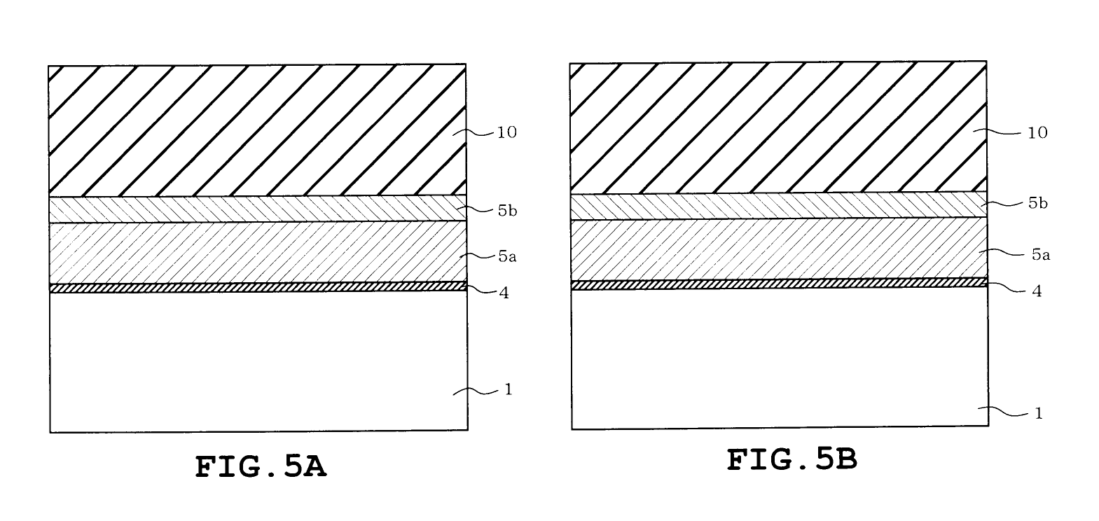

Referring now to FIG. 5A and 5B, on top of upper polycrystalline silicon film 5b, silicon oxide film 10 is formed so as to be approximately 50 nm to 400 nm thick by CVD. Silicon oxide film 10 is used a hard mask in the etching process and thus, is formed in the aforementioned range of thickness to suit its purpose.

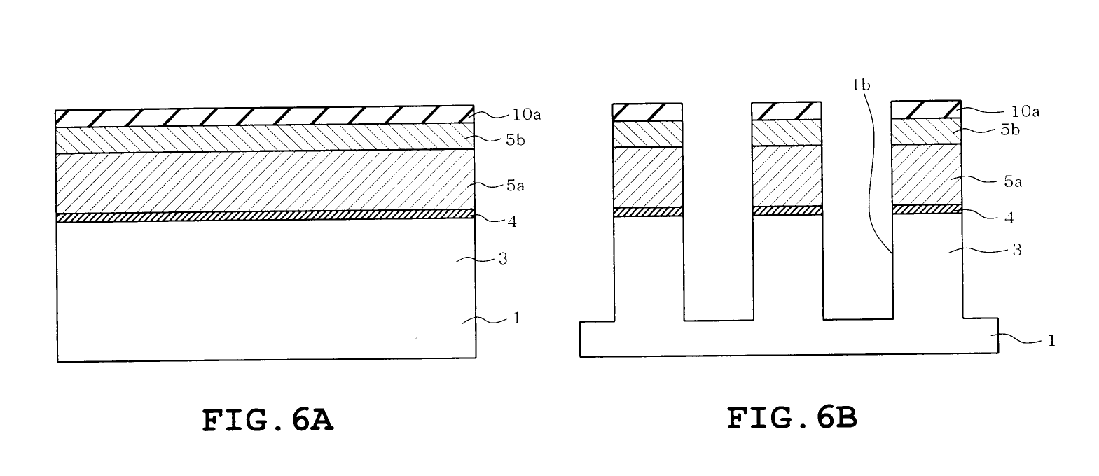

Referring to FIGS. 6A and 6B, element isolation trench 1b is formed into silicon substrate 1. The trench formation begins with forming a photoresist on top of silicon oxide film 10 and patterning the photoresist with a predetermined line and space. Using the patterned photoresist as a mask, silicon oxide film 10 is etched anisotropically by RIE (Reactive Ion Etching) to form a hard mask. Then, using the patterned photoresist mask and the hard mask, upper polycrystalline silicon film 5b, lower polycrystalline silicon film 5a, gate insulating film 4, and silicon substrate 1 are etched in the listed sequence to obtain element isolation trench lb shown in FIG. 6B. As etching progresses, the patterned photoresist is etched away and the hard mask formed by the patterned silicon oxide film 10 is thinned to be left on the feature as mask 10a.

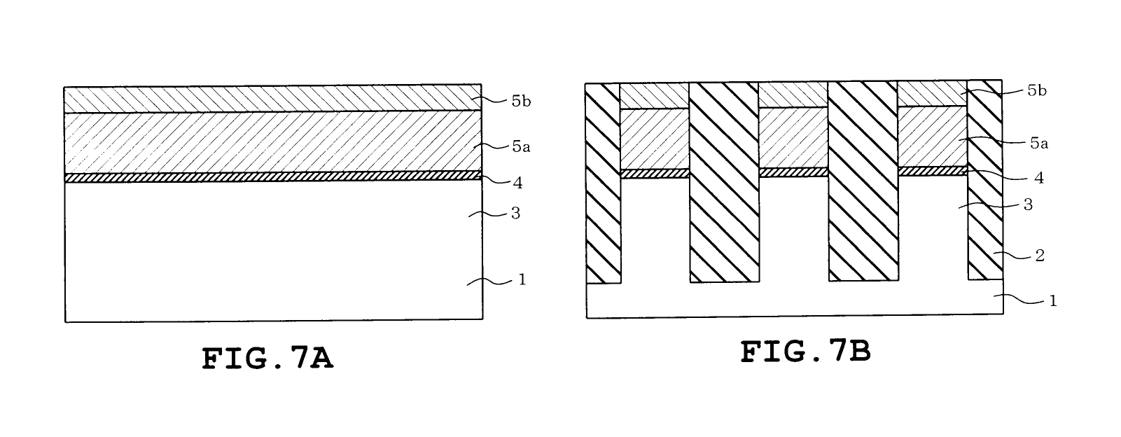

Referring to FIG. 7B, element isolation trench 1b is filled with element isolation insulating film 2 made of silicon oxide film. Though optional, the trench fill begins with a thermal oxidation of the feature to cure any damaging inside element isolation trench 1b. Then, by CVD or spin on glass coating technique, whichever is appropriate, element isolation trench 1b is overfilled by the silicon oxide film. Then, the resulting feature is planarized by chemical mechanical polishing to polish away the overfilled silicon oxide film and silicon oxide film (remainder mask) 10a overlying upper polycrystalline silicon film 5b.

Upper polycrystalline silicon film 5b serves as a polish-stop for CMP. Because upper polycrystalline silicon film 5b is doped with carbon, it suffers no surface scratches unlike a typical polycrystalline silicon film such as lower polycrystalline silicon film 5a which is only doped with phosphorous. Upper polycrystalline silicon film 5b is made less susceptible to scratching because it has become harder by being doped with carbon as will be later verified.

Approximately 2 nm to 3 nm of upper polycrystalline silicon film 5b serving as the polish stop is polished away in the CMP. However, if thermal oxidation is optionally executed after formation of element isolation trench 1b, approximately 2 nm of the upper portion of upper polycrystalline silicon film 5b becomes oxidated. Thus, 5 nm or thicker upper polycrystalline silicon film 5b with carbon dope is formed. 10 nm or thicker upper polycrystalline silicon film 5b is preferable to absorb variance in process capacity and 15 nm or thicker upper polycrystalline silicon film 5b is even more preferable to that effect. 30 nm or less thickness is advantageous in terms of reducing the aspect ratio.

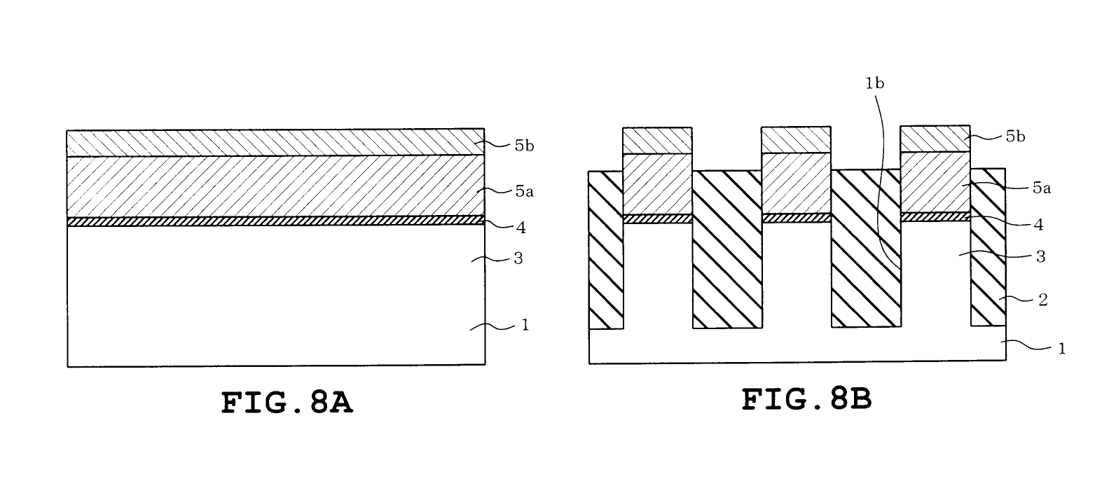

Referring to FIG. 8B, element isolation insulating film 2 filled in element isolation trench 1b is selectively etched by wet etching or dry etching. The upper surface of element isolation film 2 is thus, etched down to be substantially at level with the mid elevation of sidewall of lower polycrystalline silicon film 5a constituting floating gate electrode 5. This depressed feature is aimed to fine tune the coupling properties of the gate electrode provided in the memory cell transistor.

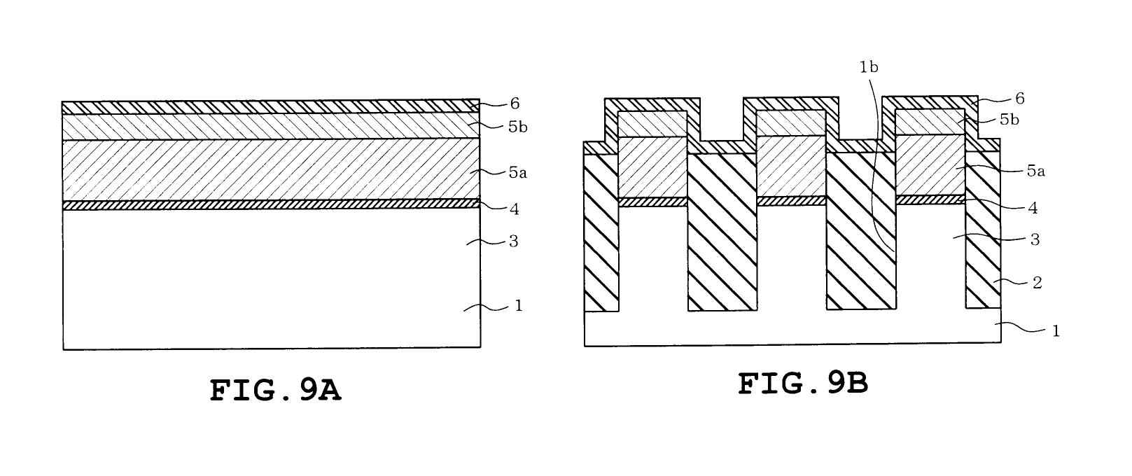

Referring to FIGS. 9A and 9B, inter-electrode insulating film 6 is formed entirely over the underlying feature so as to be lined along the upper surface and the two opposing sidewalls of the exposed upper polycrystalline silicon film 5b, the two opposing upper sidewalls of lower polycrystalline silicon film 5a, and the upper surface of element isolation insulating film 2. Inter-electrode insulating film 6 is formed into a thickness ranging between 5 nm to 20 nm by CVD. Inter-electrode insulating film 6 may be formed as a single layer of high dielectric constant insulating film or as laminated layers of silicon oxide film/high dielectric constant insulating film/silicon oxide film or silicon oxide film/silicon nitride film/silicon oxide film generally referred to as an ONO film, or as a five layer NONON film which contains an additional nitride film layer on the top and the underside of ONO film.

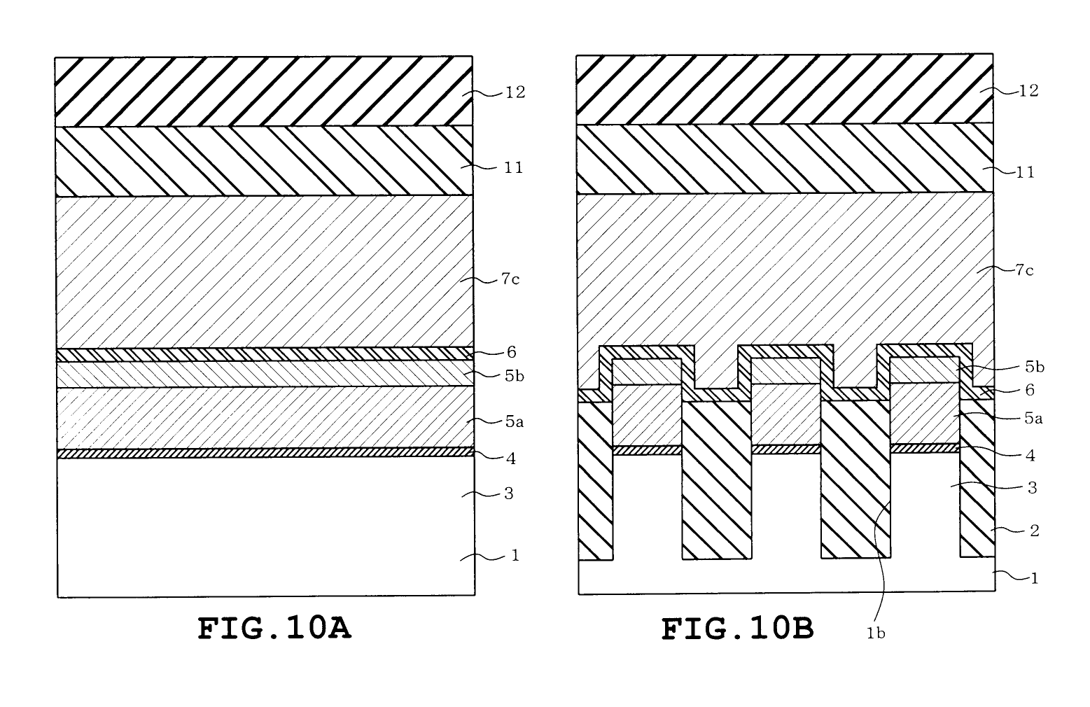

Referring to now to FIG. 10A and 10B, on top of inter-electrode insulating film 6, polycrystalline silicon film 7c serving as control gate electrode 7 is formed in the thickness ranging between 50 nm to 150 nm by CVD. Polycrystalline silicon film 7c contains impurities such as phosphorous (P) and arsenic (As). On top of polycrystalline silicon film 7c, silicon nitride film 11 is formed by CVD in the thickness ranging between 50 nm to 200 nm. Further, silicon nitride film 11 is topped with silicon oxide film 12 in the thickness ranging between 50 nm to 400 nm.

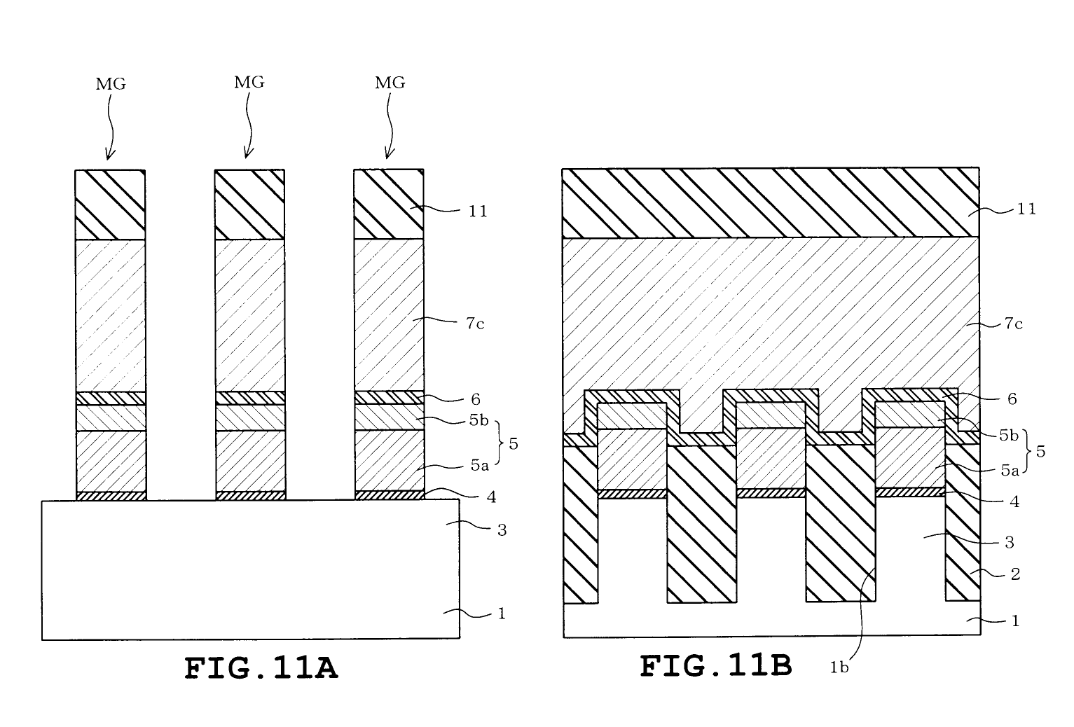

Referring to FIG. 11A, the features are isolated to form gate electrodes such as gate electrode MG of the memory cell transistor. More specifically, photoresist is coated over silicon oxide film 12 and is thereafter patterned with a predetermined line and space. Using the patterned photoresist as a mask, silicon oxide film 12 is etched into a hard mask whereafter the patterned photoresist is removed.

Then, silicon nitride film 11 is etched using the hard mask made of silicon oxide film 12. Using the etched silicon nitride film 11 as a mask, polycrystalline silicon film 7c, inter-electrode insulating film 6, upper polycrystalline silicon film 5b, lower polycrystalline silicon film 5a, and gate insulating film 4 are etched in the listed sequence to form gate electrode MG. Thus , floating gate electrode 5 provided with lower polycrystalline silicon film 5a and upper polycrystalline silicon film 5b is formed. Polycrystalline silicon film 7c is silicided later in the manufacturing process flow to form control gate electrode 7 containing lower polycrystalline silicon layer 7a and silicide layer 7b.

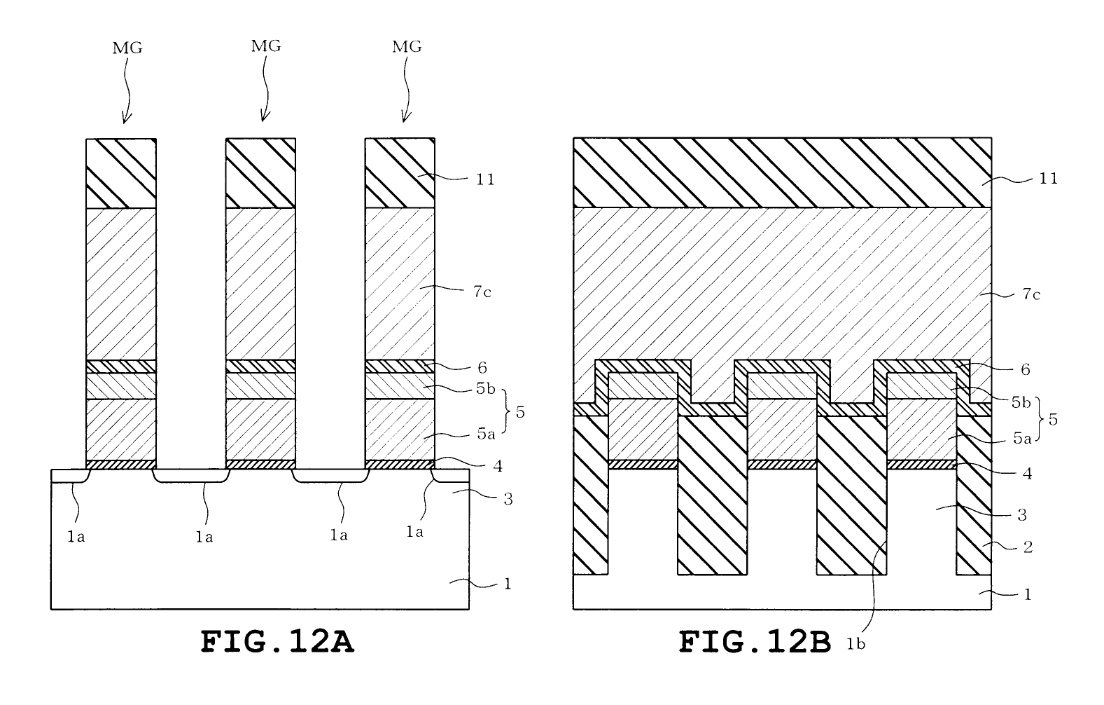

Referring now to FIG. 12A, impurity diffusion region 1a is formed by ion implantation in the surface layer of silicon substrate 1 exposed between gate electrodes MG. Impurities implanted by ion implantation are, for instance, phosphorous (P) and arsenic (As) which are n type relative to silicon. After ion implantation, thermal treatment is carried out to activate the implanted impurities to obtain impurity diffusion region 1a.

FIG. 12A shows impurity diffusion region 1a formed in the memory cell region. Though not shown nor described in detail herein, NAND flash memory is also provided with a peripheral circuit region in addition to the memory cell region in which an impurity diffusion region for the same is formed in the surface layer of silicon substrate 1 in the same manner. In order to eliminate negative by-products of microfabrication such as short channel effect that could lead to malfunctioning of transistors, structures such as LDD (Lightly Doped Drain) and DDD (Double Diffused Drain) are preferably employed that utilize sidewall insulation techniques when forming the impurity diffusion region for elements such as transistors in the peripheral circuit region. Such structures can be formed, for instance, by forming a silicon oxide film over the gate structure and anisotropically etching the silicon oxide film to leave it in part over the sidewall of the gate, whereafter ions are implanted to form a self-aligned gate.

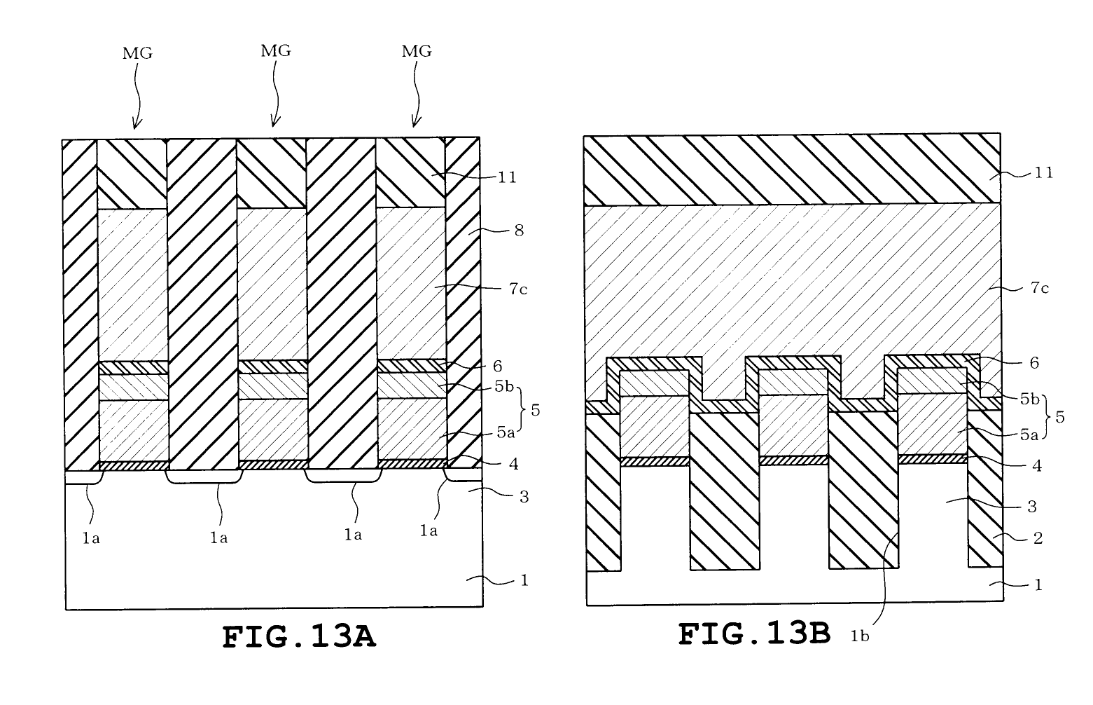

Referring now to FIG. 13A, inter-cell insulating film 8 is filled into the gaps between gate electrodes MG. Inter-cell insulating film 8 is formed, for instance, by a silicon oxide film employing TEOS or low dielectric constant insulating film for preventing circuit errors originating from increased capacitance between the memory cells. To elaborate on the gap filling process, first, inter-cell insulating film 8 is overfilled into the gaps between gate electrodes MG formed as described above so as to cover the entire feature. Then, inter-cell insulating film 8 on top of gate electrode MG is removed by anisotropic etching and inter-cell insulating film 8 filled between the gaps of gate electrode MG is lowered in elevation so as to be substantially at level with the upper surface of silicon nitride film 11 to exhibit a generally planar surface.

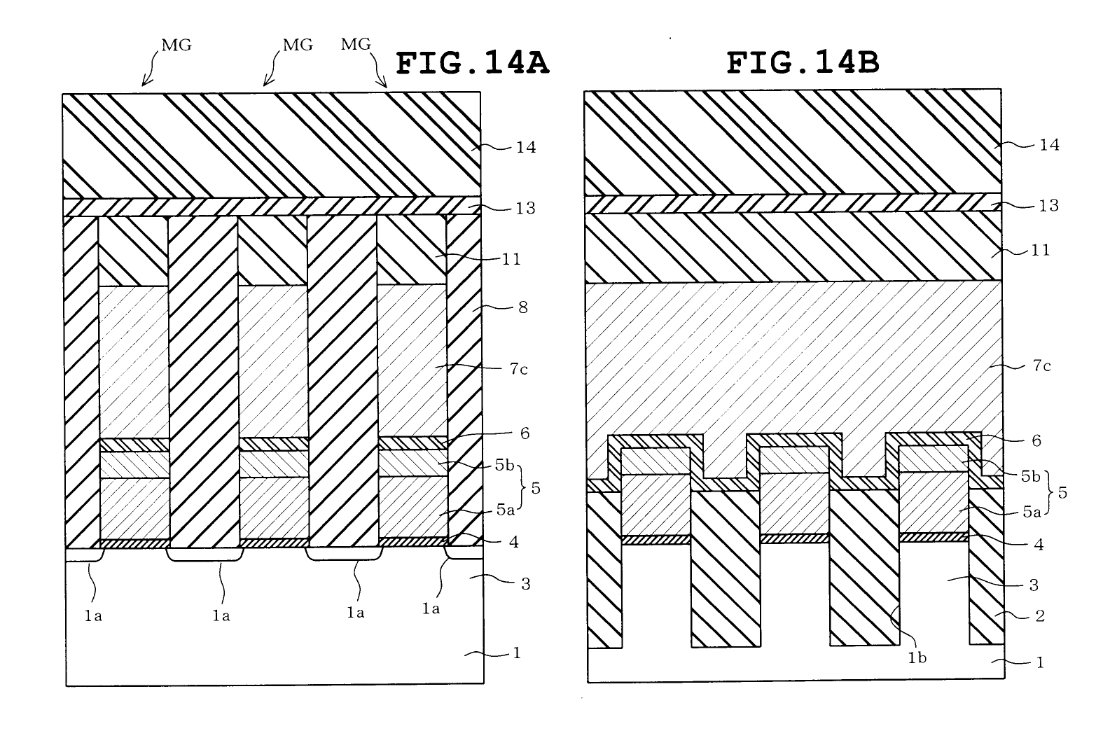

Referring to FIGS. 14A and 14B, barrier insulating film 13 is formed over silicon nitride film 11 and inter-cell insulating film 8, and insulating film 14 is further formed on top of barrier insulating film 13 to fill the recesses situated in regions other than the memory cell region. Barrier insulating film 13, typically made of silicon nitride film, varies in etching rate from inter-cell insulating film 8 and serves as a barrier to hydrogen. Another purpose for forming insulating film 14 is to fill the remaining recesses situated in the memory cell region besides gate electrode MG gaps which were not filled by inter-cell insulating film 8. To meet such requirements, insulating film 14 is preferably made of materials such as a BSPG (boro—phospho—silicate) film with high flowability suitable for planarizing deep and wide trenches.

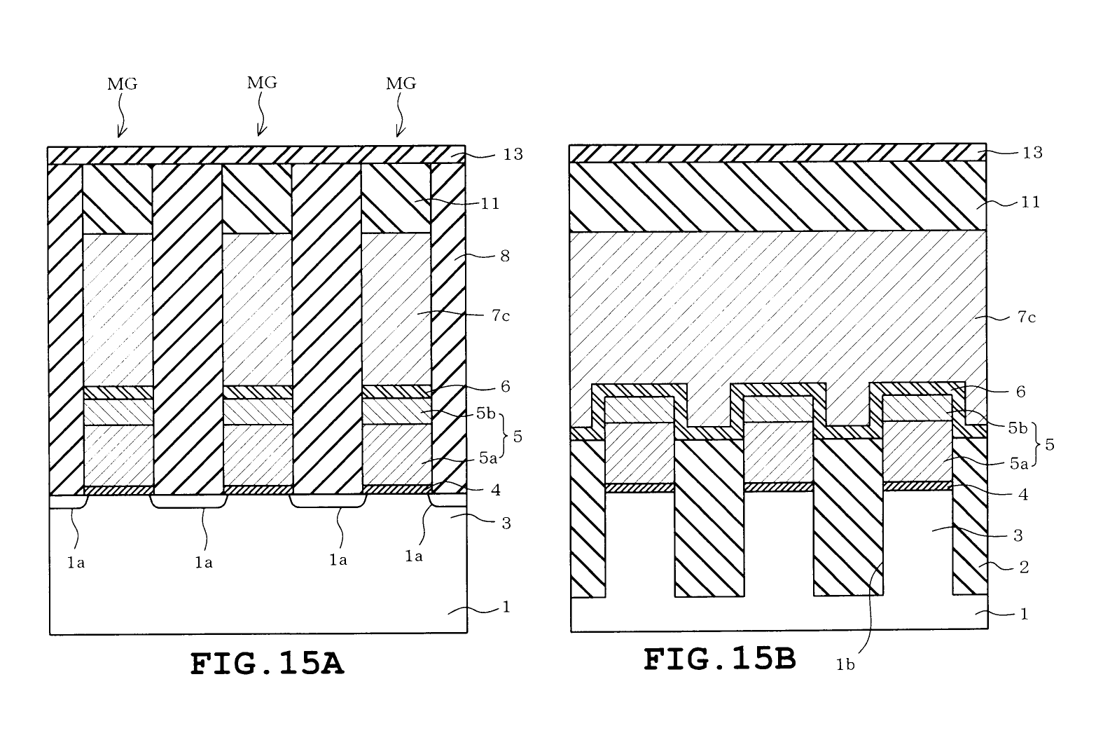

Referring to FIGS. 15A and 15B, insulating film 14 filled in the aforementioned recesses not shown is planarized by CMP to the extent that the recesses remain filled by insulating film 14. Barrier insulating film 13 made of silicon nitride film serves as a polish stop for CMP.

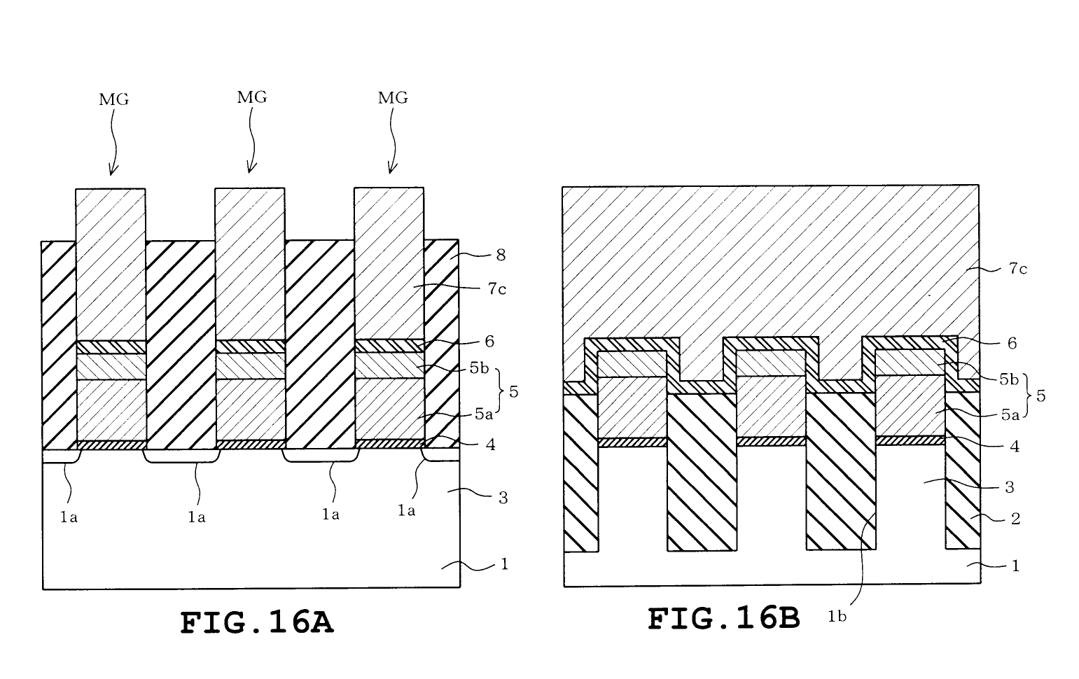

Then, as shown in FIGS. 16A and 16B, barrier insulating film 13 and silicon nitride film 11 are etched away and inter-cell insulating film 8 is etched down to a predetermined elevation by anisotropic etching as shown in FIG. 16A to expose the upper portion of polycrystalline silicon film 7c which is later processed into control gate electrode 7. Because the upper surface of intercell insulating film 8 is lowered below the upper surface of polycrystalline silicon film 7c which ultimately constitutes control gate electrode 7, polycrystalline silicon film 7c has relatively greater exposure to metal when silicided and thus, improving the efficiency of silicidation.

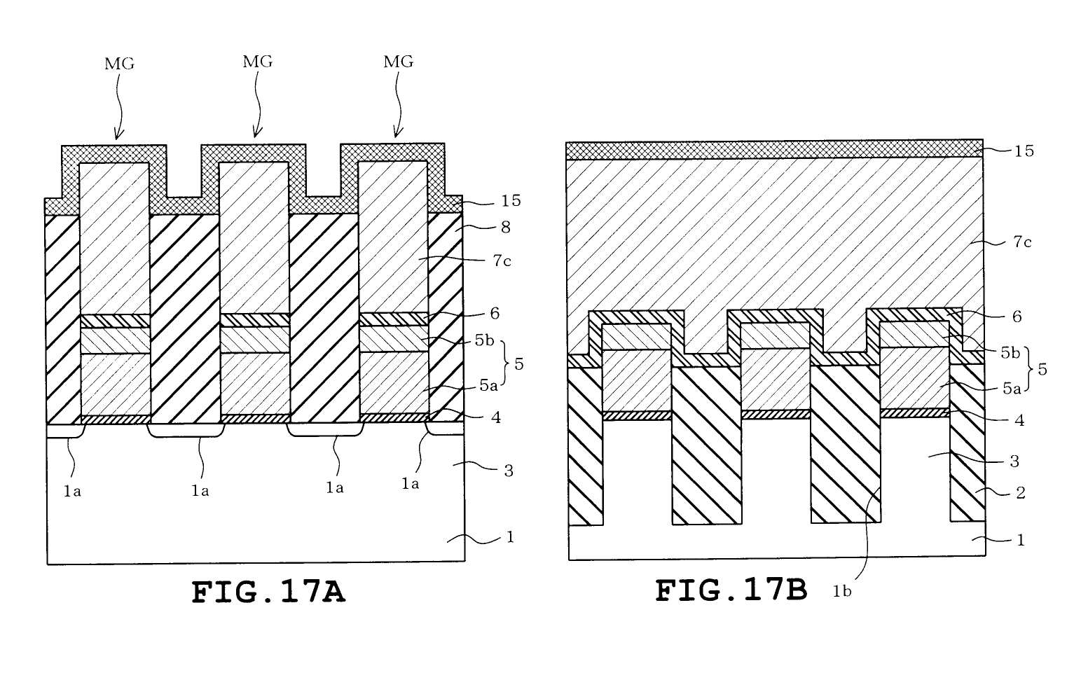

Referring to FIGS. 17A and 17B, nickel (Ni) film 15 is formed in a predetermined thickness over the entire feature by sputtering. As a result, nickel film 15 is lined along the upper surface and the upper sidewall of polycrystalline silicon film 7c and the upper surface of inter-cell insulating film 8 exposed between polycrystalline silicon film 7c pillars. Because purity of the interface of metal and silicon, in this case, nickel film 15 and polycrystalline silicon film 7c is of critical importance in silicidation, it is preferable to clean the surface of polycrystalline silicon film 7c by wet or dry etching prior to the nickel sputter.

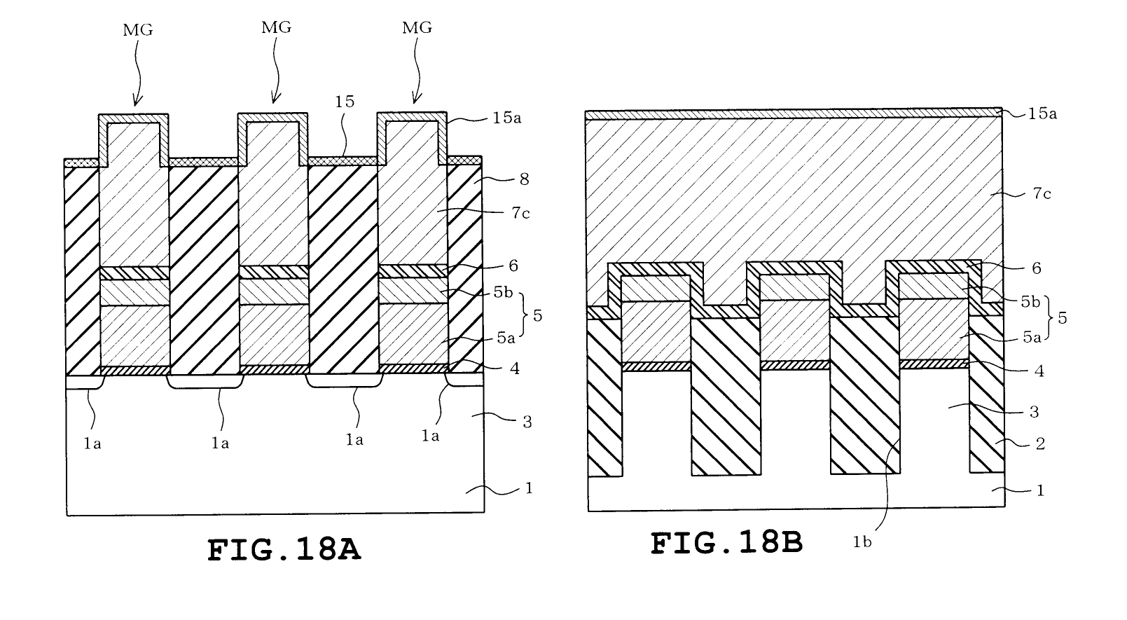

Referring now to FIGS. 18A and 18B, RTA (Rapid Thermal Anneal) is carried out to initiate reaction of nickel film 15 and polycrystalline silicon film 7c for forming nickel silicide (NiSi) layer 7b. One possible approach for forming a silicide by thermal treatment is known in which the nickel film overlying the insulating film is thermally treated in the temperature of 400 degrees Celsius or greater. In such case, however, the nickel film easily agglomerates to possibly form a so called whisker which leads to problems such as shorting of word lines and unintended silicidation in unwanted areas. Such risks may be addressed by executing the thermal treatment in two different stages.

The first thermal treatment is carried out after nickel film 15 formation at a temperature ranging between 250 to 400 degrees Celsius for a duration of 5 minutes or less. The portion of nickel film 15 contacting silicon is transformed into a nickel rich silicide film 15a including a dinickel silicide (Ni₂Si) or a mixture of dinickel silicide (Ni₂Si) and nickel monosilicide (NiSi). Further, during the low temperature thermal treatment, the nickel above insulating film which does not contact polycrystalline silicon film 7c, in other words, most of nickel film 15 above inter-cell insulating film 8 remains non-reactive without agglomerating.

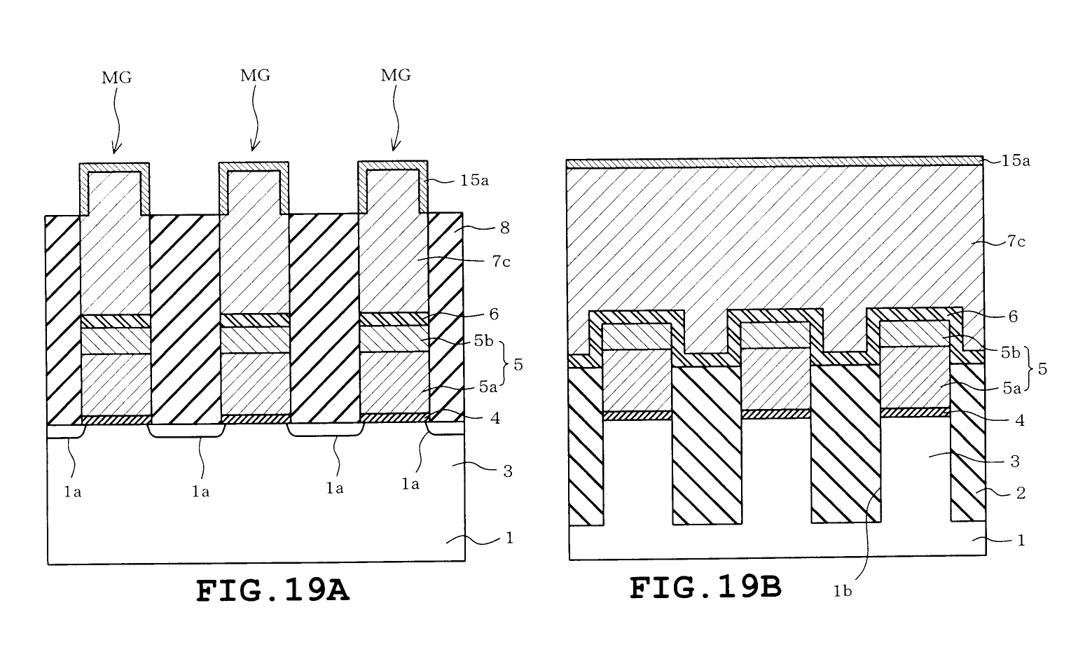

Next, referring to FIG. 19A, non-reactive nickel film 15 remaining above inter-cell insulating film 8 is selectively removed by sulfuric acid hydrogen peroxide mixture or alkali hydrogen peroxide mixture. Thus, nickel rich silicide film 15a which has reacted with nickel film 15 at the upper surface and side surface of polycrystalline silicon film 7c remains as can be seen in FIG. 19A.

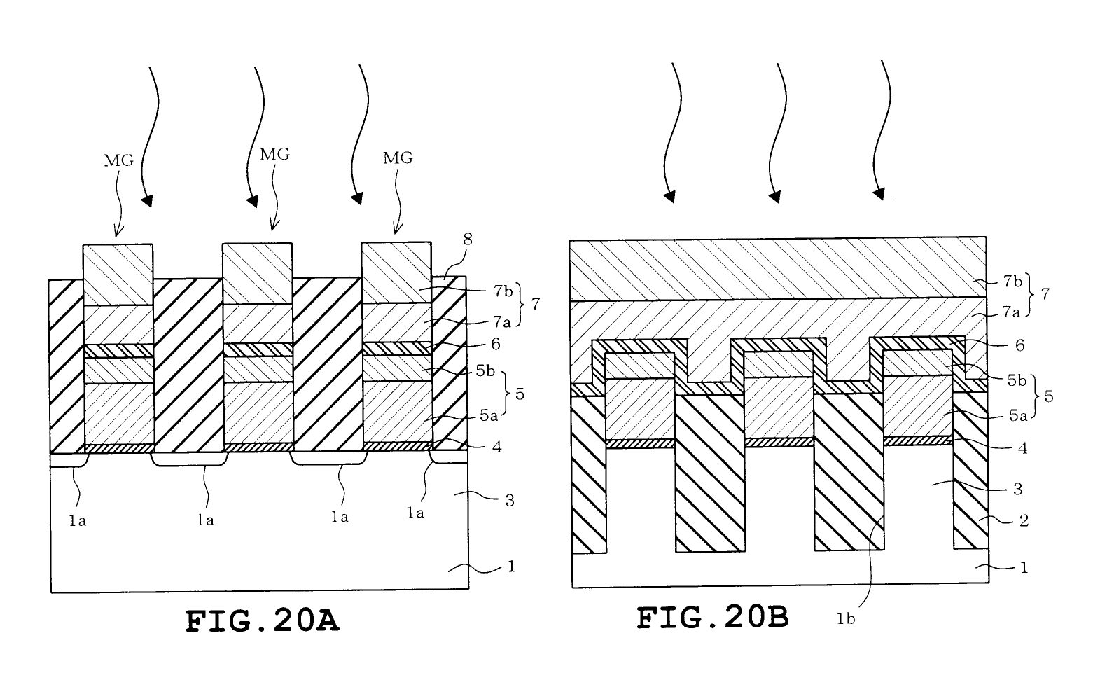

Then, in FIGS. 20A and 20B, the second thermal treatment is carried out for 5 minutes or less under the temperature ranging between 450 degrees Celsius and 550 degrees Celsius. Thus, the nickel rich silicide film 15a promotes the silicidation of polycrystalline silicon film 7c to transform its upper portion into silicide layer 7b made of nickel monosilicide. As a result, a half or more than half of polycrystalline silicon film 7c turns into silicide layer 7b and the rest remains as polycrystalline silicon layer 7a. Thus, control grate electrode 7 is obtained that comprises polycrystalline silicon layer 7a and silicide layer 7b. The thickness of silicide layer 7b can be controlled by varying the thickness of the sputter nickel film 15. In another exemplary embodiment, control gate electrode 7 may be formed such that polycrystalline silicon film 7c is fully silicided.

Then, referring back to FIGS. 3A and 3B, silicon oxide film serving as interlayer insulating film 9 is formed by plasma CVD, which is followed by steps for contact and interconnect formation to obtain a chip of NAND flash memory device.

According to the above described exemplary embodiment, floating gate electrode 5 of the memory cell transistor has been obtained by forming a hard upper polycrystalline silicon film 5b doped with carbon above lower polycrystalline silicon film 5a. Thus, the hardened upper polycrystalline silicon film 5b may serve as a polish stop during CMP which suffers relatively less scratching. Such tolerance to scratches eliminates the need for an additional polish-stop, typically a silicon nitride film, which was conventionally required, to thereby reduce the overall elevation of the gate electrode and consequently the aspect ratio. Reduced aspect ratio eliminates disadvantages such as pattern collapse typically encountered after formation of element isolation trenches lb to improve yield in device manufacturing.

Further, upper polycrystalline silicon film 5b is doped with carbon having a dopant concentration of 1×10¹⁸ atoms/cm³ or greater and typically configured to range between 2×10²⁰ to 2×10²¹ atoms/cm³. The inventors have verified through experiments that upper polycrystalline silicon film 5b treated as described above exhibits excellent anti-scratch performance when used as polish stop for CMP to qualify for commercial use.

Upper polycrystalline silicon film 5b doped with carbon exhibits improved tolerance to oxidation during thermal treatment. This prevents formation of bird's beak in inter-electrode insulating film 6 formed over upper polycrystalline silicon film 5b to improve the reliability of the device properties.

The inventors have verified the relation between the dopant concentration of carbon added to upper polycrystalline silicon film 5b and the behavior of scratch formation by comparing the samples no. 1 to 3 created under the following conditions (1) to (3). The number of each sample corresponds to the number of the condition in which they were created. The samples were subjected to CMP and were evaluated by their measurement of scratch formation.

Samples no. 1 to 3 were prepared so that each included a base material made of a silicon substrate and 100 nm of thermal oxidation film formed on top of the silicon substrate.

Sample no. 1 was further provided with (1) 100 nm of carbon-free polycrystalline silicon film formed on top of the base material.

Sample no. 2 was further provided with (2) 70 nm of lower polycrystalline silicon film formed on top of the base material and 30 nm of upper polycrystalline silicon film formed on top of the lower polycrystalline silicon film so as to contain carbon in a dopant concentration of 2×10²⁰ atoms/cm³ by being subjected to 10 sccm of ethylene (C₂H₄) gas.

Sample no. 3 was further provided with (3) 70 nm of lower polycrystalline silicon film formed on top of the base material and 30 nm of upper polycrystalline silicon film formed on top of the lower polycrystalline silicon film doped with carbon in a dopant concentration of 2×10²¹ atoms/cm³ by being subjected to 100 sccm of ethylene (C₂H₄) gas.

Results of CMP performed on samples no. 1 to 3 showed that no scratches were observed in samples no. 2 and 3 which were doped with carbon. As evidenced above, according to the above described exemplary embodiment, formation of scratches can be completely eliminated in the CMP when carbon was added to the upper polycrystalline silicon film in the dopant concentration of 2×10²⁰ atoms/cm³ or greater. Such level of dopant concentration can be obtained by flowing 10 sccm or more ethylene (C₂H₄) gas when forming the upper polycrystalline silicon film.

It can be drawn from the above described exemplary embodiment that scratch formation was eliminated in upper polycrystalline silicon film 5b doped with carbon because it exhibited greater level of hardness compared to an ordinary polycrystalline silicon film free of carbon. A carbon-free polycrystalline silicon film, however, contains naturally occurring or inevitable carbon impurities which cannot be measured. Thus, stated differently, a measurable concentration of carbon within the polycrystalline silicon film will suffice to eliminate or at least reduce scratch formation. Grounds of scratch formation in CMP are also attributable to polish parameters such as slurry particle diameter or polish particle diameter, and polish rate. Generally, CMP performed with greater polish rate and greater slurry particle diameter renders the features scratch prone, however reduced polish rate and reduced slurry particle diameter prolongs the duration of the polishing, and thus, polish parameters need to be adjusted depending upon process capability. To recap, scratch formation can be reduced if 1×10¹⁸ atoms/cm³ or greater carbon is added to the polycrystalline silicon film which is a level of dopant concentration that exceeds the naturally occurring or inevitable carbon impurities contained in the polycrystalline silicon film.

The present exemplary embodiment is not limited to the foregoing exemplary embodiment but may be modified or expanded as follows.

Ethylene (C₂H₄) gas used in incorporating carbon into upper polycrystalline silicon film may be replaced by other organic, in other words, carbon including gases. Further, instead of exposing the upper polycrystalline silicon film to carbon containing gas, carbon may be incorporated into carbon-free polycrystalline silicon film by ion implantation.

In addition to adding carbon into the upper layer, more specifically, the upper polycrystalline silicon film 5b of floating gate electrode 5, a layer doped with carbon may further be formed on gate insulating film 4 side of lower polycrystalline silicon film 5a, in other words, the lower layer/portion of floating gate electrode 5 while keeping the intermediate layer of the floating gate electrode 5 carbon free. Such configuration advantageously prevents bird's beak formation at the edge of gate insulating film 4.

Further, control gate electrode 7 may likewise include a polycrystalline silicon film doped with carbon as was the case for floating gate electrode 5. Provision of a carbon added layer at the lower layer of control gate electrode 7 advantageously prevents bird's beak formation as well as improving the reliability of device properties. Providing a carbon added layer at the upper layer of control gate electrode 7 improves the tolerance of the silicide. As described above, the carbon added layer may be provided at both upper and lower layers of control gate electrode 7.

The features of the present disclosure have been described through application to NAND flash memory device, however, they may be applied to NOR flash memory device and other nonvolatile storage devices that employ a floating gate electrode configuration.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device, comprising:
a semiconductor substrate including a surface layer;
an element isolation insulating film isolating the surface layer of the semiconductor device into a plurality of active regions;
a first gate insulating film formed above the active regions;
a charge storing layer formed above the first gate insulating film and including a silicon layer containing an upper layer selectively doped with carbon;
a second gate insulating film formed above the charge storing layer; and
a control gate electrode formed above the second gate insulating film.

2. The device according to claim 1, wherein a dopant concentration of carbon within the upper layer of the silicon layer is equal to or greater than 1×10¹⁸ atoms/cm³.

3. The device according to claim 1, wherein a dopant concentration of carbon within the upper layer of the silicon layer ranges between 2×10²⁰ to 2×10²¹ atoms/cm³.

4. The device according to claim 1, wherein the charge storing layer is doped with either of phosphorous and arsenic having a dopant concentration ranging between 1×10²⁰ to 1×10²¹ atoms/cm³.

5. The device according to claim 1, wherein the silicon layer of the charge storing layer comprises a lower polycrystalline silicon film free of carbon and an upper polycrystalline silicon film doped with carbon.

6. The device according to claim 5, wherein a resistor element comprising a laminate including the lower polycrystalline silicon film and the upper polycrystalline silicon film is formed in a peripheral circuit region.

7. The device according to claim 1, wherein the silicon layer of the charge storing layer further contains an intermediate layer free of carbon and a lower layer doped with carbon.

8. The device according to claim 1, wherein the second gate insulating film comprises an oxide-nitride-oxide film.

9. The device according to claim 1, wherein the control gate electrode includes a silicon layer doped with carbon or a silicide layer doped with carbon.

10. The device according to claim 9, wherein the silicon layer of the control gate electrode doped with carbon is provided in a lower layer of the control gate electrode.

11. The device according to claim 9, wherein the silicide layer of the control gate electrode doped with carbon is provided in an upper layer of the control gate electrode.

12. A method of manufacturing a nonvolatile semiconductor storage device, comprising:
preparing a semiconductor substrate;
forming a first gate insulating film above the semiconductor substrate;
forming a charge storing layer above the first gate insulating film, the charge storing layer including a silicon layer being doped with carbon at least in an upper layer thereof;
forming an element isolation trench into the semiconductor substrate through the charge storing layer and the first gate insulating film;
filling the element isolation trench with an insulating film;
polishing the insulating film until an upper surface of the charge storing layer is exposed and the insulating film remains in the element isolation trench to obtain an element isolation insulating film;
forming a second gate insulating film above the charge storing layer after forming the element isolation insulating film; and
forming a control gate electrode above the second gate insulating film.

13. The method according to claim 12, wherein the charge storing layer is formed by low pressure chemical vapor deposition.

14. The method of claim 12, wherein forming the charge storing layer includes adding carbon into the upper layer of the silicon layer with a dopant concentration equal to or greater than 1×10¹⁸ atoms/cm³.

15. The method of claim 12, wherein forming the charge storing layer includes adding carbon into the upper layer of the silicon layer with a dopant concentration ranging between 2×10²⁰ to 2×10²¹ atoms/cm³.

16. The method of claim 12, wherein forming the charge storing layer includes adding either of phosphorous and arsenic having a dopant concentration ranging between 1×10²⁰ to 1×10²¹ atoms/cm³.

17. The method of claim 12, wherein forming the charge storing layer includes forming a lower polycrystalline silicon film free of carbon and forming an upper polycrystalline silicon film doped with carbon above the lower polycrystalline silicon film.

18. The method of claim 17, wherein the upper polycrystalline silicon film is 5 nm to 30 nm thick.

19. The method of claim 12, wherein forming the charge storing layer includes further adding carbon to a lower layer of the silicon layer of the charge storing layer.

20. The method of claim 12, wherein forming the control gate electrode includes forming a silicon layer doped with carbon.
